(19) United States
(12) Patent Application Publication
(10) Pub. No.: US 2011/0088758 A1
(43) Pub. Date: Apr. 21, 2011

(54) GLASS PASTE COMPOSITION, ELECTRODE SUBSTRATE PREPARED USING SAME, METHOD OF PREPARING ELECTRODE SUBSTRATE, AND DYE SENSITIZED SOLAR CELL INCLUDING ELECTRODE SUBSTRATE

(76) Inventors: Tadao Yagi, Yokohama (JP); Yukika Yamada, Yokohama (JP); Yoshitaka Terao, Yokohama (JP); Jong-Ki Lee, Yongin-si (KR); Nam-Choul Yang, Yongin-si (KR); Hyun-Chul Kim, Yongin-si (KR); Jung-Tae Park, Yongin-si (KR)

(21) Appl. No.: 12/906,966

(22) Filed: Oct. 18, 2010

(30) Foreign Application Priority Data
Oct. 19, 2009 (JP) 2009-240472
May 18, 2010 (KR) 10-2010-0046509

(51) Int. Cl. H01L 51/46; C03C 8/14; B05D 5/12

(52) U.S. Cl. 136/252; 501/17; 427/74

(57) ABSTRACT

According to embodiments of the invention, a glass paste composition for a dye sensitized solar cell includes a glass frit, an organic binder, and an organic solvent.

### CROSS-REFERENCE TO RELATED APPLICATIONS

This application claims priority to and the benefit of Japanese Patent Application No. 2009-240472 filed in the Japanese Patent Office on Oct. 19, 2009, and Korean Patent Application No. 10-2010-0046509 filed in the Korean Intellectual Property Office on May 18, 2010, the entire contents of which are incorporated herein by reference.

### BACKGROUND

1. Field

This disclosure relates to glass paste compositions, electrode substrates prepared using the same, methods of preparing the electrode substrates, and dye sensitized solar cells including the electrode substrates.

2. Description of the Related Art

Photoelectric conversion devices, such as solar cells, that convert photoenergy into electrical energy have been actively researched in an effort to provide clean energy having little environmental impact.

Some examples of solar cells include silicon-based solar cells (such as monocrystalline silicon solar cells, polysilicon solar cells, amorphous silicon solar cells, and the like), and compound semiconductor solar cells using compound semiconductors (such as cadmium telluride, copper indium selenide, and the like) instead of silicon. However, conventional solar cells are high in cost, raw materials are scarce, and the solar cells have prolonged energy recycle times.

Although solar cells using organic materials in an effort to achieve large area and low cost have been suggested, conversion efficiency and durability are still insufficient.

Dye sensitized solar cells using a porous semiconductor body have been suggested. For example, a dye sensitized solar cell including a Gratzel cell in which a dye is fixed on the surface of a porous titanium oxide thin film has been suggested. A Gratzel cell is a dye-sensitized photoelectric conversion cell including a working electrode of a porous titanium oxide thin film layer that is spectrally-sensitized by a ruthenium complex dye, an electrolyte layer including urea as a main component, and a counter electrode.

The Gratzel cell may provide an inexpensive photoelectric conversion device since it includes an inexpensive oxide semiconductor such as titanium oxide. Also, the Gratzel cell may provide a relatively high conversion efficiency since the ruthenium complex dye adsorbs a wide region of visible rays. The dye sensitized solar cell is reported to have a conversion efficiency of over 12%, so it has sufficient practicality compared to silicon-based solar cells.

Generally, when a photoelectric conversion device (such as a solar cell) is enlarged, the photoelectric conversion efficiency may decrease since the generated current is converted into Joule heat in the low-conductive substrate (such as a transparent electrode). In order to overcome this problem, attempts have been undertaken to form a highly conductive metal line such as silver and copper in a grid to provide a current-collecting line (i.e., a current-collecting electrode, or grid electrode), so as to decrease electrical energy loss in the solar cell.

When the current-collecting line is provided in a dye sensitized solar cell, measures must be taken to prevent corrosion of the current-collecting line due to the electrolyte solution including urea. It has also been suggested that a current-collecting line can be coated or protected with a glass material having a low melting point. When the baking temperature of the glass material having a low melting point for coating the current-collecting line is higher than the strain point of the substrate, the substrate may be too warped to provide sufficient electrolyte solution resistance. Accordingly, sufficient electrolyte solution resistance may not be provided.

Therefore it has been suggested to bake at a temperature lower than the strain point. In addition, it has been suggested to use materials in which the glass material for coating the current-collecting line has a coefficient of linear expansion that is less different from the substrate to prevent cracking of the coating film. However, the coating film is stressed after baking the glass material for the coating film, causing cracks.

### SUMMARY

According to embodiments of the present invention, a glass paste composition may prevent a coating film coated on a current-collecting electrode from generating cracks while providing sufficient electrolyte solution resistance.

According to other embodiments of the present invention, an electrode substrate employs the glass paste composition.

According to further embodiments of the present invention, a dye sensitized solar cell includes the electrode substrate.

According to still further embodiments of the present invention, a method of manufacturing the electrode substrate is provided.

In some embodiments, a glass paste composition for a dye sensitized solar cell includes a glass frit, an organic binder, and an organic solvent. The organic binder may include at least one of acrylic resin or methacrylic resin obtained by emulsion polymerization, and the de-binding temperature of the organic binder is lower than the glass transition temperature of the glass frit. The organic binder may include particles having a number average particle diameter of about 50 nm to about 3000 nm. The organic binder may include particles that swell in the organic solvent.

According to other embodiments, an electrode substrate for a dye sensitized solar cell includes a current-collecting electrode disposed on a transparent conductive substrate, and a coating film coated on the surface of the current-collecting electrode. The coating film is obtained by coating the glass paste composition on the surface of current-collecting electrode and baking the same.

According still other embodiments, a dye sensitized solar cell includes the electrode substrate.

According to further embodiments, a method of preparing the electrode substrate includes coating the glass paste composition on the surface of the current-collecting electrode disposed on a transparent conductive substrate, and baking the glass paste composition to provide a coating film coated on the surface of the current-collecting electrode.

During preparation of the electrode substrate, the glass paste composition may be coated by screen printing or coating using a dispenser.

The glass paste composition according to some embodiments may prevent and suppress crack generation in the coating film coated on the current-collecting electrode and provide good electrolyte solution resistance. Thus, the glass paste composition may impart higher efficiency and a longer life-span to a dye sensitized solar cell including the electrode substrate obtained using the glass paste composition.

### BRIEF DESCRIPTION OF THE DRAWINGS

FIG. 1 is a diagram of a structure of a dye sensitized solar cell according to one embodiment of the present invention.

FIG. 2 is a diagram schematically depicting the connection of an inorganic metal oxide semiconductor to a dye according to one embodiment of the present invention.

FIG. 3 is a diagram of a structure of an electrode substrate according to one embodiment of the present invention.

FIG. 4A and FIG. 4B are diagrams depicting the structure of the coating film disposed on the electrode substrate shown in FIG. 3.

FIG. 5 is a graph showing the results of thermogravimetry/differential thermal analysis (TG/DTA) of an acryl-based resin according to one embodiment of the present invention.

FIG. 6A and FIG. 6B are microscope photographs of an acryl-based resin obtained by emulsion polymerization according to one embodiment of the present invention.

### DETAILED DESCRIPTION

Exemplary embodiments of the present invention will now be described. However, these embodiments are only exemplary, and the present invention is not limited thereto. In the present specification and drawings, like elements having substantially equivalent functions are designated with the same reference numeral, and repetitive descriptions are omitted.

In order to improve electrolyte solution resistance, a variety of kinds of glass paste compositions having low melting points have been investigated by the present inventors. Thereby, it has been found that the electrolyte solution resistance is significantly affected by pores having sizes of several tens of μm to several hundreds of μm generated in the coating film while baking the glass material, as well as by the relationship between the baking temperature and the strain point of the substrate and the difference in the coefficient of linear expansion between the glass material and the substrate. In other words, when the pores present in the coating film are comparatively large after baking the glass material, cracks may be generated in the coating film during manufacture of a dye sensitized solar cell. From these results, it has been found that cracks in the coating film may be prevented by suppressing the generation of large-sized pores in the coating film when baking the glass material.

### Structure of Dye Sensitized Solar Cell

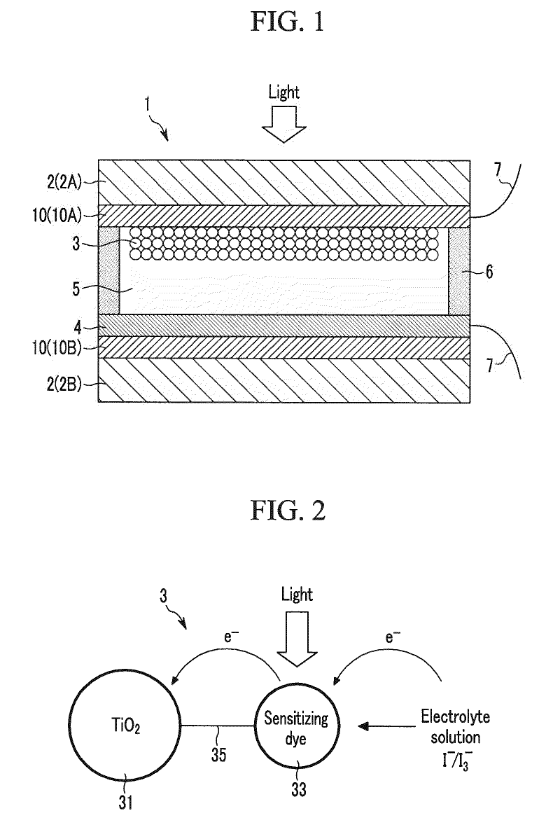

First, FIGS. 1 and 2 depict the structure of a dye sensitized solar cell according to embodiments of the present invention. FIG. 1 is a diagram illustrating the structure of a dye sensitized solar cell 1 according to one embodiment. FIG. 2 is a diagram schematically illustrating the connection of the inorganic metal oxide semiconductor to the dye. Hereinafter, the dye sensitized solar cell 1 including a Gratzel cell shown in FIG. 1 is described as an example.

As shown in FIG. 1, the dye sensitized solar cell 1 according to embodiments of the present invention includes two substrates 2, two electrode substrates 10, a photoelectrode 3 (working electrode), a counter electrode 4, an electrolyte solution 5, a spacer 6, and a lead wire 7.

### Substrate

Two substrates 2 (2A and 2B) are disposed to face each other with a gap (e.g., a predetermined gap) therebetween. The material for each substrate 2 is not specifically limited as long as it is a transparent material having a little light adsorption from the visible ray region to the near infrared ray region of extraneous light (solar light etc.).

The substrate 2 may include, for example: a glass substrate such as quartz, common glass, BK7, lead glass, or the like; or a resin substrate such as polyethylene terephthalate, polyethylene naphthalate, polyimide, polyester, polyethylene, polycarbonate, polyvinylbutyrate, polypropylene, tetraacetyl cellulose, syndiotactic polystyrene, polyphenylene sulfide, polyarylate, polysulfone, polyester sulfone, polyetherimide, cyclic polyolefin, phenoxy bromide, vinyl chloride, and the like.

### Electrode Substrate

The electrode substrates 10 (10A and 10B) are respectively formed on a surface of the substrates 2 (2A and 2B) on at least a light incident side (i.e., a side where light is incident from the outside). Each electrode substrate 10 (10A and 10B) includes, for example, a transparent electrode including a transparent conductive oxide (TCO). In order to improve photoelectric conversion efficiency, the sheet resistance (surface resistance) of the electrode substrates 10 may be decreased by as much as possible, for example, up to 20 Ω/cm²(Ω/sq) or less.

However, in some embodiments, the electrode substrate 10B may be omitted (i.e., it is not disposed on the surface of the substrate 2B facing the substrate 2A). In other embodiments, the substrate 2B need not be transparent (i.e., having little light adsorption in the region from the visible ray region to the near infrared ray region of extraneous light) even if the electrode substrate 10B is provided.

The electrode substrate according to one embodiment will now be described.

### Photoelectrode (Working Electrode)

In the dye sensitized solar cell 1, the photoelectrode 3 includes an inorganic metal oxide semiconductor layer having a photoconversion function and is formed as a porous layer. For example, as shown in FIG. 1 and FIG. 2, the photoelectrode 3 is formed by laminating a plurality of particulates 31 of an inorganic metal oxide semiconductor, e.g. TiO₂ or the like (hereinafter referred to a “metal oxide particulate 31”), on the surface of the electrode substrate 10 which is a porous body (nanoporous layer) including nanometer-sized pores in the laminated metal oxide particulate 31.

The photoelectrode 3 is formed as a porous body including a plurality of small pores as described above, so that it may increase the surface area of the photoelectrode 3 and connect a large amount of sensitizing dye 33 to the surface of the metal oxide particulate 31. Thereby, the dye sensitized solar cell 1 may have high photoelectric conversion efficiency.

As shown in FIG. 2, a sensitizing dye 33 is connected to the surface of the metal oxide particulate 31 through a connecting group 35 to provide a photoelectrode 3 in which the inorganic metal oxide semiconductor is sensitized.

The term “connection” indicates that the inorganic metal oxide semiconductor is chemically and physically bonded with the sensitizing dye (for example, bonded by adsorption or the like). Accordingly, the term “connecting group” indicates inclusion of an anchor group or an adsorbing group as well as a chemical functional group.

Although FIG. 2 shows that one sensitizing dye 33 unit is connected to the surface of the metal oxide particulate 31, FIG. 2 is only a schematic, and the present invention is not limited thereto.

In order to improve the electrical output of the dye sensitized solar cell 1, the number of sensitizing dye 33 units connected to the surface of the metal oxide particulate 31 may be increased as much as possible to coat a plurality of sensitizing dye 33 units on the surface of metal oxide particulate 31 to cover as much area as possible.

When the number of sensitizing dye 33 units is increased, an excited electron is recombined due to the interaction between adjacent sensitizing dye 33 units such that it is difficult to output electrical energy. Accordingly, a co-adsorption material such as deoxycholic acid may be used to maintain an appropriate distance and to coat the sensitizing dye 33 units.

The photoelectrode 3 may be formed by laminating the metal oxide particulate 31 in a plurality of layers. The metal oxide particulate 31 may include primary particles having a number average particle diameter of about 20 nm to about 100 nm. The photoelectrode 3 has a layer thickness of several μm (e.g., up to about 10 μm). When the photoelectrode 3 has a layer thickness of less than several μm, the light transmitted through the photoelectrode 3 may be increased and the sensitizing dye 33 may be insufficiently excited, and the efficient photoelectric conversion efficiency may not be obtained.

On the other hand, when the photoelectrode 3 has a layer thickness of greater than several μm, the distance between the surface of the photoelectrode 3 (i.e., the surface of the side contacting the electrolyte solution 5) and the electric conductive surface (i.e., the interface between the photoelectrode 3 and the electrode substrate 10) is increased, making it difficult to effectively transmit generated excited electrons to the electric conductive surface. Therefore, good conversion efficiency may not be provided.

A metal oxide particulate 31 and a sensitizing dye 33 for a photoelectrode 3 according to some embodiments will now be described.

### Metal Oxide Particulate

The inorganic metal oxide semiconductor generally photoelectrically converts light in a predetermined wavelength region, but it is possible to photoelectrically convert the light in the region from visible rays to near infrared rays by connecting the sensitizing dye 33 to the surface of the metal oxide particulate 31.

The compound for a metal oxide particulate 31 is not specifically limited as long as it enhances the photoelectric conversion function by being connected with the sensitizing dye 33. Nonlimiting examples of the metal oxide particulate include titanium oxide, tin oxide, tungsten oxide, zinc oxide, indium oxide, niobium oxide, iron oxide, nickel oxide, cobalt oxide, strontium oxide, tantalum oxide, antimony oxide, oxides of lanthanide elements, yttrium oxide, vanadium oxide, and the like.

As the surface of the metal oxide particulate 31 is sensitized by the sensitizing dye 33, in some embodiments the conduction band of the inorganic metal oxide may be disposed in a place that receives electrons from a photoexcitation trap of the sensitizing dye 33. In this regard, the compound for a metal oxide particulate 31 may include, for example, titanium oxide, tin oxide, zinc oxide, niobium oxide, and the like. In some embodiments, for example, the metal oxide particulate may include titanium oxide in view of cost and environmental sanitation. The metal oxide particulate 31 may include a single kind of inorganic metal oxide or may include a mixture of multiple kinds inorganic metal oxides.

### Sensitizing Dye

The sensitizing dye 33 is not specifically limited as long as the metal oxide particulate 31 photoelectrically converts light in a region having no photoelectric conversion function (for example, the region from visible rays to near infrared rays). Nonlimiting examples of the sensitizing dye include azo-based dyes, quinacridone-based dyes, diketopyrrolopyrrole-based dyes, squarylium-based dyes, cyanine-based dyes, merocyanine-based dyes, triphenylmethane-based dyes, xanthene-based dyes, porphyrin-based dyes, chlorophyll-based dyes, ruthenium complex-based dyes, indigo-based dyes, perylene-based dyes, dioxadine-based dyes, anthraquinone-based dyes, phthalocyanine-based dyes, naphthalocyanine-based dyes, derivatives thereof, and the like.

The sensitizing dye 33 may include a functional group including a connecting group 35 capable of connecting to the surface of the metal oxide particulate 31 in order to promptly transmit excited electrons from the photo-excited dye into the conductive band of the inorganic metal oxide. The functional group is not specifically limited as long as it is capable of connecting the sensitizing dye 33 to the surface of the metal oxide particulate 31 to enable the prompt transmission of excited electrons from the dye to the conductive band of the inorganic metal oxide. Nonlimiting examples of the functional group include carboxyl groups, hydroxyl groups, hydroxamic acid groups, sulfonic acid groups, phosphonic acid groups, phosphinic acid groups, and the like.

### Counter Electrode

The counter electrode 4 may be a positive electrode of the dye sensitized solar cell 1 and may include a film disposed on the surface of the substrate 2B facing the substrate 2A on which the electrode substrate 10A is formed to face the electrode substrate 10B. In other words, the counter electrode 4 is disposed to face the photoelectrode 3 on the surface of the electrode substrate 10A in the region surrounded by the two electrode substrates 10 (10A and 10B) and the spacer 6. A metal catalyst layer having conductivity is disposed on the surface of the counter electrode 4 (i.e., the surface facing the photoelectrode 3).

The conductive material for the metal catalyst layer of the counter electrode 4 may include, for example, a metal (e.g., platinum, gold, silver, copper, aluminum, rhodium, indium, or the like), a metal oxide (e.g., indium tin oxide (ITO), tin oxide (including fluorine doped tin oxide and the like), zinc oxide, and the like), a conductive carbon material, a conductive organic material, and the like.

The layer thickness of the counter electrode 4 is not specifically limited, but in some embodiments, the thickness may range, for example, from about 5 nm to about 10 μm.

Lead wires 7 are respectively connected to the electrode substrate 10A (on the photoelectrode 3) and the counter electrode 4. The lead wire 7 from the electrode substrate 10A and the lead wire 7 from the counter electrode 4 are connected outside of the dye sensitized solar cell 1 to provide a current circuit.

In addition, the electrode substrate 10A and the counter electrode 4 are partitioned by a spacer 6 leaving a gap (e.g., a predetermined gap) therebetween. The spacer 6 is formed along the circumference (or edges) of the electrode substrate 10A and the counter electrode 4, and the spacer seals the space between the electrode substrate 10A and the counter electrode 4. The spacer 6 may be a resin having a good sealing properties and high corrosion resistance. For example, the resin may include a thermoplastic resin film, a photo-curable resin, an ionomer resin, a glass frit, or the like.

The ionomer resin may include, for example, Himilan (trade name) manufactured by Mitsui DuPont PolyChemical K.K, or the like.

### Electrolyte Solution

An electrolyte solution 5 is injected into the space between the electrode substrate 10A and the counter electrode 4, and is sealed therein by the spacer 6.

The electrolyte solution 5 may include, for example, an electrolyte, a medium, and additives. The electrolyte may include a redox electrolyte such as an I₃⁻/I⁻-based or Br₃⁻/Br⁻-based electrolyte. Nonlimiting examples of the electrolyte include mixtures of I₂ and iodide (e.g., LiI, Nal, Kl, CsI, Mgl₂, CaI₂, CuI, tetraalkylammonium iodide, pyridinium iodide, imidazolium iodide, and the like), mixtures of Br₂ and bromide (e.g., LiBr etc.), organic melt salt compounds, and the like.

The organic melt salt compound may be a compound including an organic cation and an inorganic or organic anion, and has a melting point of room temperature or lower. The organic cation of the organic melt salt compound may include aromatic cations. Nonlimiting examples of organic aromatic cations include N-alkyl-N′-alkylimidazolium cations (such as N-methyl-N-ethylimidazolium cations, N-methyl-N′-n-propylimidazolium cations, N-methyl-N′-n-hexylimidazolium cations, and the like), and N-alkylpyridinium cations (such as N-hexylpyridinium cations, N-butylpyridinium cations, and the like). In addition, the organic cation may be an aliphatic cation (nonlimiting examples of which include N,N,N-trimethyl-N-propylammonium cations and the like), or a cyclic aliphatic cation (nonlimiting examples of which include N,N-methylpyrrolidinium cations and the like).

The inorganic or organic anion for the organic melt salt compound may include, for example: halide ions such as chloride ions, bromide ions, iodide ions, and the like; inorganic anions such as phosphorus hexafluoride ions, boron tetrafluoride ions, methane sulphonic trifluoride ions, perchloric acid ions, hypochloric acid ions, chloric acid ions, sulfonic acid ions, phosphoric acid ions, and the like; amide anions; or imide anions such as bis(trifluoromethylsulfonyl)imide ions and the like. In some embodiments, the organic melt salt compound may be any of the compounds discussed in Inorganic Chemistry, vol. 35 (1996); p. 1168 to p. 1178, the entire contents of which are incorporated herein by reference.

The mentioned iodide, bromide, or the like may be used singularly or as a mixture thereof. Particularly, the electrolyte may include a mixture of I₂ and iodide (for example, I₂ and LiI), pyridinium iodide, or imidazolium iodide or the like, but is not limited thereto.

The electrolyte solution 5 may have a concentration of I₂ of about 0.01 M to about 0.5 M, and a concentration of either or both of iodide and bromide (e.g., when a mixture thereof is used) of about 0.1 M to about 15 M.

The medium for the electrolyte solution 5 may be any compound providing good ion conductivity. Nonlimiting examples of the liquid medium include: ether compounds such as dioxane, diethylether, and the like; linear ethers such as ethylene glycol dialkylether, propylene glycol dialkylether, polyethylene glycol dialkylether, polypropylene glycol dialkylether, and the like; alcohols such as methanol, ethanol, ethylene glycol monoalkylether, propylene glycol monoalkylether, polyethylene glycol monoalkylether, polypropylene glycol monoalkylether, and the like; polyhydric alcohols such as ethylene glycol, propylene glycol, polyethylene glycol, polypropylene glycol, glycerine, and the like; nitrile compounds such as acetonitrile, glutarodinitrile, methoxy acetonitrile, propionitrile, benzonitrile, and the like; carbonate compounds such as ethylene carbonate, propylene carbonate, and the like; heterocyclic ring compounds such as 3-methyl-2-oxazolidinone and the like; aprotic polar materials such as dimethyl sulfoxide, sulfolane, and the like; water; and the like. The medium may include a single medium or a mixture of mediums.

To use a solid medium (including a gel), a polymer may be added to a liquid medium. In this case, a polymer such as polyacrylonitrile, polyvinylidene fluoride, or the like may be added to the liquid medium, or a multi-functional monomer including an ethylenically unsaturated group may be polymerized in the liquid medium to provide a solid medium.

The electrolyte solution 5 may also include a hole transport material such as CuI, CuSCN (these compounds are p-type semiconductors not requiring a liquid medium and act as an electrolyte), or a hole transporting material such as 2,2′,7,7′-tetrakis(N,N-di-p-methoxyphenylamine)-9,9′-spirobifluorene disclosed in Nature, vol. 395 (Oct. 8, 1998), p583 to p585, the entire contents of which are incorporated herein by reference, or the like.

Other additives may be further added to the electrolyte solution 5 in order to improve the durability or electrical output of the dye sensitized solar cell 1. Nonlimiting additives for improving durability include inorganic salts such as magnesium iodide or the like. Nonlimiting additive for improving electrical output include: amines such as t-butyl pyridine, 2-picoline, 2,6-lutidine, or the like; steroids such as deoxy cholic acid or the like; monosaccharides or sugar alcohols such as glucose, glucosamine, glucuronic acid, or the like; disaccharides such as maltose or the like; linear oligosaccharides such as raffinose or the like; cyclic oligosaccharides such as cyclodextrin or the like; or hydrolysis oligosaccharides such as lacto oligosaccharide or the like.

In addition, the thickness of the layer injected with the electrolyte solution 5 and sealed is not specifically limited, but the thickness may be selected to substantially prevent direct contact between the counter electrode 4 and the photoelectrode 3 adsorbed with the dye. In some embodiments, for example, the thickness may range from about 0.1 μm to about 100 μm.

### Working Principle of Dye Sensitized Solar Cell

In the photoelectrode 3 including the metal oxide particulate 31 and the sensitizing dye 33 connected to the surface of the metal oxide particulate 31 through the connecting group 35, the sensitizing dye 33 is excited to release excited electrons when light contacts the sensitizing dye 33 connected to the surface of the metal oxide particulate 31. The released excited electrons are transmitted to the conductive band of the metal oxide particulate 31 through the connecting group 35.

The excited electrons having arrived at the metal oxide particulate 31 are transmitted to another metal oxide particulate 31 until they reach the electrode substrate 10, and are then released to the outside of the dye sensitized solar cell 1 through the lead wire 7.

Meanwhile, the sensitizing dye 33 (where there is a lack of electrons since the excited electrons are released) receives electrons supplied from the counter electrode 4 through the electrolyte (such as I⁻/I₃⁻ or the like) in the electrolyte solution 5, thereby returning to the electrically neutral state.

### Electrode Substrate 10

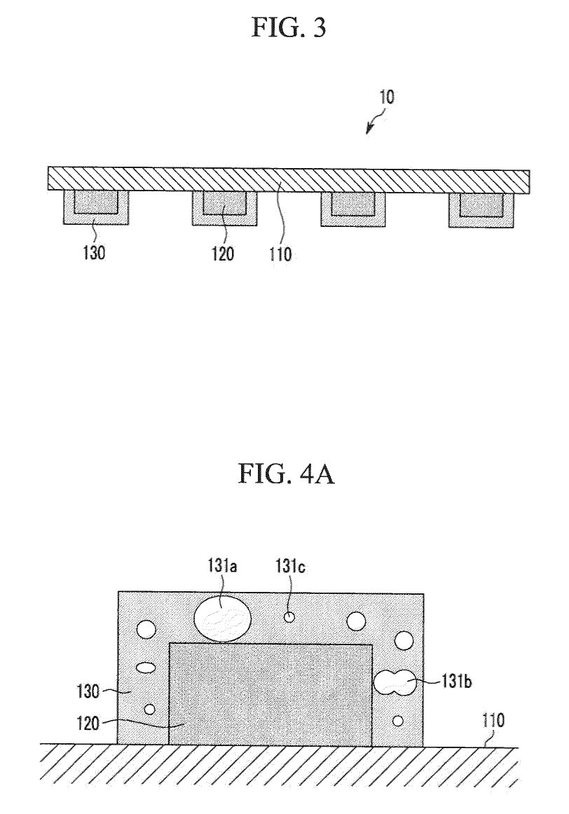

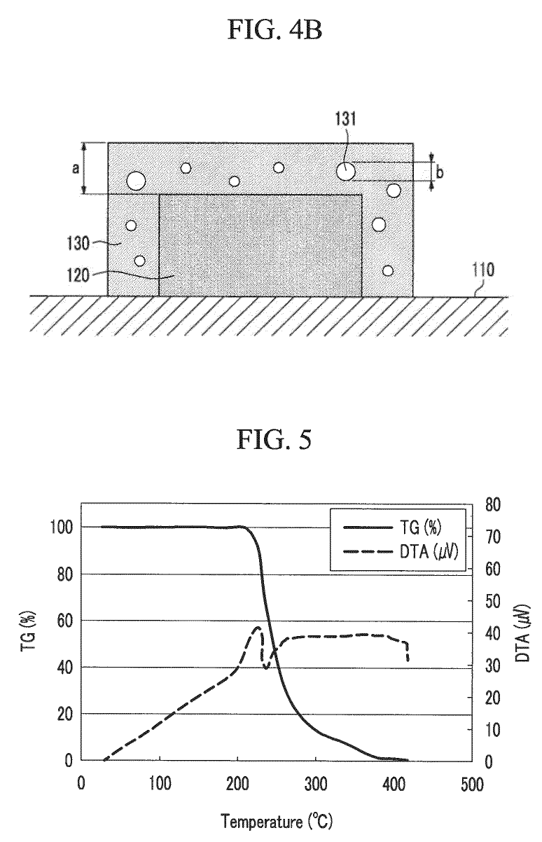

The general structure of the dye sensitized solar cell 1 according to embodiments of the present invention is described above. The electrode substrate 10 according to embodiments of the present invention will now be described with reference to FIGS. 3, 4A, and 4B.

FIG. 3 is a diagram showing the structure of an electrode substrate 10 according to embodiments of the present invention. FIGS. 4A and 4B are diagrams showing the structure of a coating film formed on the electrode substrate 10 shown in FIG. 3. As shown in FIG. 3, the electrode substrate 10 according to embodiments of the present invention includes a transparent electrode 110, a current-collecting electrode 120, and a coating film 130.

### Transparent Electrode 110

The transparent electrode 110 may be formed in a layer using, for example, a transparent conductive oxide (TCO). The transparent conductive oxide is not particularly limited as long as it is a conductive material that adsorbs little light in the region from the visible rays to the infrared rays of extraneous light. Nonlimiting examples of the transparent conductive oxide include metal oxides having good conductivity such as indium tin oxide (ITO), tin oxide (SnO₂), fluorine-doped tin oxide (FTC)), antimony-included tin oxide (ITO/ATO), zinc oxide (ZnO₂), and the like.

### Current-Collecting Electrode

The current-collecting electrode 120 transmits excited electrons (i.e., the excited electrons that have arrived at the electrode substrate 10 through the metal oxide particulate 31) to the lead wire 7, and is a metal line disposed on the surface of the electrode substrate 10. The current-collecting electrode 120 generally has high sheet resistance (e.g., about 10 Ω/sq or more), and is provided to substantially prevent generated current from being converted into Joule heat in a substrate having relatively low conductivity (such as a transparent electrode 110), thereby substantially preventing deteriorations in the photoelectric conversion efficiency.

In this regard, the current-collecting electrode 120 is electrically connected to the electrode substrate 10, and the material for forming the current-collecting electrode 120 may include a highly conductive metal or alloy such as Ag, Ag/Pd, Cu, Au, Ni, Ti, Co, Cr, Al, and the like. The wire pattern of the current-collecting electrode 120 is not particularly limited as long as the shape decreases electrical energy loss. The wire pattern may be any shape, for example, a lattice, stripe, rectangular shape, comb tooth shape, or the like.

In some embodiments, the current-collecting electrode 120 is formed of a metal such as gold, silver, copper, platinum, aluminum, nickel, titanium, solder, or the like, making it susceptible to corrosion by the electrolyte solution 5 including iodine (I⁻/I₃⁻ or the like). Accordingly, the dye sensitized solar cell 1 according to embodiments of the present invention further includes the following coating film 130.

### Coating Film 130

The coating film 130 acts to substantially prevent or suppress corrosion of the current-collecting electrode 120 caused by the electrolyte solution 5, and it is coated around the current-collecting electrode 120 to protect the current-collecting electrode 120 from corrosion by the electrolyte solution 5. The coating film 130 is obtained by coating a glass paste composition having a low melting point on the surface of the current-collecting electrode 120 and baking the resultant product. The glass paste composition for the coating film 130 is a paste composition including a glass frit, an organic binder, and an organic solvent.

Each component of the glass paste composition will now be described.

### Glass Frit

The glass frit for the glass paste composition according to embodiments of the present invention may include a SiO₂ skeleton, a B₂O₃ skeleton, or a P₂O₅ skeleton and other metal oxides in order to control the melting point and provide chemical stability. For example, the glass frit may include a low melting point glass based on SiO₂—Bi₂O₃-MOₓ, B₂O₃—Bi₂O₃-MOₓ, SiO₂—CaO—Na(K)₂O-MO, P₂O₅—MgO-MOₓ (where M is at least one kind of metal element), or the like. The glass frit in the glass paste composition may include a single glass frit or a mixture of glass frits.

### Organic Binder

The organic binder for the glass paste composition according to embodiments of the present invention includes a resin having a de-binding temperature that is lower than the glass transition temperature of the glass frit. For example, the organic binder may include at least one of an acrylic resin or a methacrylic resin.

In general, the acrylic resin or methacrylic resin may be manufactured according to one of three methods: 1) a solution polymerization method including dissolving a monomer in a solvent to perform solution polymerization; 2) a suspension polymerization method including vigorously stirring a monomer in a solvent in which the monomer and the produced polymer are not dissolved and performing polymerization; and 3) an emulsion polymerization method including performing a polymerization reaction in a state in which a water-insoluble or weakly water soluble vinyl compound is dispersed in water with an emulsifier.

According to embodiments of the present invention, the acrylic resin or methacrylic resin is obtained by emulsion polymerization. The reason the organic binder for a glass paste composition according to one embodiment has a de-binding temperature lower than the glass transition temperature of glass frit, and includes at least one acrylic resin or methacrylic resin obtained by emulsion polymerization according to some embodiments is described as follows.

As in the electrode substrate 10 according to some embodiments, when the coating film 130 coated on the current-collecting electrode 120 is obtained by baking a low melting point glass paste composition. The organic binder remains in the glass paste composition during the baking process, and is combusted during the baking process to produce gas in the coating film 130. The gas is present in the coating film 130 as pores 131, as shown in FIG. 4A and FIG. 4B.

The pores 131 may be present in a variety of shapes and sizes, such as large pores 131a resulting from the generation of a large volume of gas, large pores 131b formed from the agglomeration of a plurality of smaller pores, and small pores 131c, as shown in FIG. 4A.

According to the investigations performed by the present inventors into the pores 131 present in the coating layer 130 after the baking process, it has been found that the size of the pores 131 present in the coating layer after the baking process significantly affects the electrolyte solution resistance of the electrode substrate 10 formed with the current-collecting electrode 120. In other words, if large pores (131a, 131b, etc.) are present in the coating layer 130 as shown in FIG. 4A, cracks easily generate from the pores (131a, 131b, etc.) in the coating film 130, or the electrolyte solution 5 contacts the current-collecting electrode 120 through the pores, thereby corroding the current-collecting electrode 120.

Accordingly, the present inventors researched the reason that large pores 131a and 131b are generated in the coating layer 130. As a result of this research, the inventors found that the organic binder remains in the glass paste composition during baking, and that the organic binder is gasified during baking, thereby generating large pores 131a and 131b in the coating layer 130.

Accordingly, in embodiments of the present invention, the generation of large pores 131a and 131b in the coating film 130 may be suppressed by decreasing the amount of organic binder remaining during baking of the glass paste composition. According to some embodiments of the present invention, in order to decrease the amount of organic binder remaining during baking the glass paste composition, the organic binder for a glass paste composition includes a resin having a de-binding temperature that is lower than the glass transition temperature of the glass frit. Since the resin has a de-binding temperature that is lower than the glass transition temperature of glass frit, almost all of the organic binder has already evaporated by the time the temperature rises above the glass transition temperature of the glass frit during the baking process. As such, the generation of large pores 131a and 131b during the baking process of the glass paste composition may be substantially suppressed.

According to embodiments of the present invention, the organic binder may include at least one of an acrylic resin or a methacrylic resin (hereinafter referred to as “acryl-based resin”) since such an acryl-based resin has a de-binding temperature (about 390° C. to about 410° C.) that is lower than the glass transition temperature of the glass frit.

In some embodiments, the glass frit is one based on SiO₂—Bi₂O₃-MOX, B₂O₃—Bi₂O₃-MOX, SiO₂—CaO—Na (K)₂O-MO, or P₂O₅—MgO-MOX (where M is at least one kind of metal element), which have glass transition temperatures of about 400° C. to about 420° C.

If the organic resin used as the organic binder has a de-binding temperature higher than the glass transition temperature of the glass frit (i.e., about 400° C. to about 420° C.), it is possible that the organic resin may remain during baking of the glass paste composition so as to generate large pores 131a and 131b in the coating film 130. In addition, if the de-binding temperature of the organic resin that is used as the organic binder is too high, the baking temperature must be further increased in order to evaporate the organic binder.

Also, the transparent electrode 110 increases in resistance due to the baking process. Accordingly, the resistance may be further increased in proportion to the increase in baking temperature, thereby increasing electrical loss during the photoelectric conversion.

In this regard, according to some embodiments, the organic binder includes an acryl-based resin. The organic binder may include, for example, an acryl-based resin having a de-binding temperature of about 400° C. or less.

The de-binding temperature of the acryl-based resin may be measured by, for example, thermogravimetry/differential thermal analysis (TG/DTA) under conditions such as an air atmosphere and a temperature-increasing speed (for example, predetermined speed of about 10° C./min). The temperature at which the initial weight is decreased to a specific ratio (for example, a predetermined ratio of about 2%) or less is determined to be the de-binding temperature.

FIG. 5 shows one example of the results of thermogravimetry/differential thermal analysis (TG/DTA) of an acryl-based resin according to embodiments of the present invention. As shown in FIG. 5, the weight of the acryl-based resin according to one embodiment is decreased to 2% or less from the initial weight at around 400° C. Accordingly, it is understood that the de-binding temperature of this acryl-based resin is around 400° C.

The acryl-based resin is not particularly limited, but may include a resin polymerized from a single kind of acryl-based monomer, or a resin copolymerized from multiple kinds of acryl-based monomers. For example, the organic binder may include a resin in which the acryl-based monomer is copolymerized with another monomer as a comonomer.

In addition, the acryl-based resin according to embodiments of the present invention may include a cross-linked resin prepared using a cross-linking agent.

Nonlimiting examples of the acryl-based monomer include: acrylic acid; methacrylic acid; acrylic acid esters such as alkyl acrylates (for example, methyl acrylate, ethyl acrylate, n-propyl acrylate, isopropyl acrylate, n-butyl acrylate, isobutyl acrylate, t-butyl acrylate, 2-ethylhexyl acrylate, cyclohexyl acrylate, phenyl acrylate, benzyl acrylate, phenylethyl acrylate, and the like) or hydroxy group-containing alkyl acrylates (for example, 2-hydroxyethyl acrylate, 2-hydroxypropyl acrylate, and the like), and the like; methacrylic acid esters such as alkyl methacrylates (for example, methyl methacrylate, ethyl methacrylate, n-propyl methacrylate, isopropyl methacrylate, n-butyl methacrylate, isobutyl methacrylate, t-butyl methacrylate, 2-ethylhexyl methacrylate, cyclohexyl methacrylate, phenyl methacrylate, benzyl methacrylate, phenylethyl methacrylate, and the like) or hydroxy group-containing alkyl methacrylates (for example, 2-hydroxyethyl methacrylate, 2-hydroxypropyl methacrylate, and the like), and the like; acrylamides; substituted acrylamides (for example, N-methyl acrylamide, N-methylol acrylamide, N,N-dimethylol acrylamide, N-methoxymethyl acrylamide, and the like); methacrylamides; substituted methacrylamides (for example, N-methyl methacrylamide, N-methylol methacrylamide, N,N-dimethylol methacrylamide, N-methoxymethyl methacrylamide, and the like); amino group-substituted alkyl acrylates (for example, N,N-diethylamino ethylacrylate, and the like); amino group-substituted alkyl methacrylates (for example, N,N-diethylamino methacrylate, and the like); epoxy group-containing acrylates (for example, glycidyl acrylate and the like); epoxy group-containing methacrylates (for example, glycidyl methacrylate and the like); salts of acrylic acid (for example, sodium salts, potassium salts, ammonium salts, and the like); and salts of methacrylic acid (for example, sodium salts, potassium salts, ammonium salts, and the like), and the like. The acryl-based monomer may include a single monomer or a copolymer of two or more kinds of monomers.

Nonlimiting examples of comonomers for copolymerizing with the acryl-based monomer include: styrene and derivatives thereof; unsaturated dicarboxylic acids (for example, itaconic acid, maleic acid, fumaric acid, and the like); unsaturated dicarboxylic acid esters (for example, methyl itaconic acid, dimethyl itaconic acid, methyl maleic acid, dimethyl maleic acid, methyl fumaric acid, dimethyl fumaric acid, and the like); salts of unsaturated dicarboxylic acids (for example, sodium salts, potassium salts, ammonium salts, and the like); monomer including sulfonic acid groups or salts thereof (for example, styrene sulfonic acid, vinyl sulfonic acid, and salts thereof (for example, sodium salts, potassium salts, ammonium salts, and the like)); acid anhydrides of maleic anhydride, itaconic anhydride, and the like; vinyl isocyanate; allyl isocyanate; vinylmethylether; vinylethylether; vinyl acetic acid; and the like. The monomer may be a single monomer or a copolymer of two or more kinds of monomers.

The glass paste composition according to embodiments of the present invention may form a coating film 130 coated on the current-collecting electrode 120. The provided coating film 130 may sufficiently cover the current-collecting electrode 120. However, if the coating area is too large, the conductivity of the excited electrons may deteriorate, thereby decreasing the photoelectric conversion efficiency.

According to some embodiments, the glass paste composition decreases the sticking property to facilitate the patterning process. The acryl-based resin according to embodiments of the present invention may include particles obtained by emulsion polymerization. That is, when acryl-based resin particles obtained by emulsion polymerization are used as an organic binder and are dispersed in an organic solvent, the acryl-based resin may maintain the particle shape, thereby decreasing the sticking property and improving workability during coating of the glass paste composition. In particular, the acryl-based resin particles obtained by emulsion polymerization enables patterning by screen printing, dispensing, or the like. On the other hand, other types of polymerization (e.g., solution polymerization and suspension polymerization), sticking is increased when preparing the paste, making it difficult to handle the paste and perform the patterning process.

The acryl-based resin according to embodiments of the present invention may include particles having a number average particle diameter of about 50 nm to about 3000 nm. It is very difficult to provide acryl-based resin particles having a number average particle diameter of less than about 50 nm. When the acryl-based resin has a number average particle diameter of more than about 3000 nm, the glass frit is not well-dispersed, thereby inhibiting the coating of the glass paste composition on the electrode substrate 10.

According to some embodiments, the number average particle diameter of the acryl-based resin particles is measured by image analysis using a microscope (for example, a transmission electron microscope, or the like) photograph to determine the number average particle diameter of particles present in one visual field. In addition, the number average particle diameter may also be determined by a particle diameter distribution measurer using optical scattering.

The acryl-based resin according to some embodiments may include a mixture of different particulates having a variety of number average particle diameters. In other words, the acryl-based resin particles may be prepared by associating a plurality of particulate groups having different number average particle diameters. The acryl-based resin according to some embodiments may swell and thicken by being dispersed in the organic solvent.

As used herein, the term “swelling” indicates that the surface of the acryl-based resin particles interacts with the organic solvent (i.e., the surface of the acryl-based resin particles is partially dissolved in the organic solvent) while the acryl-based resin particles maintain their particle shape. Accordingly, the particle diameter of acryl-based resin is enlarged, and simultaneously the acryl-based resin used as the organic binder is thickened.

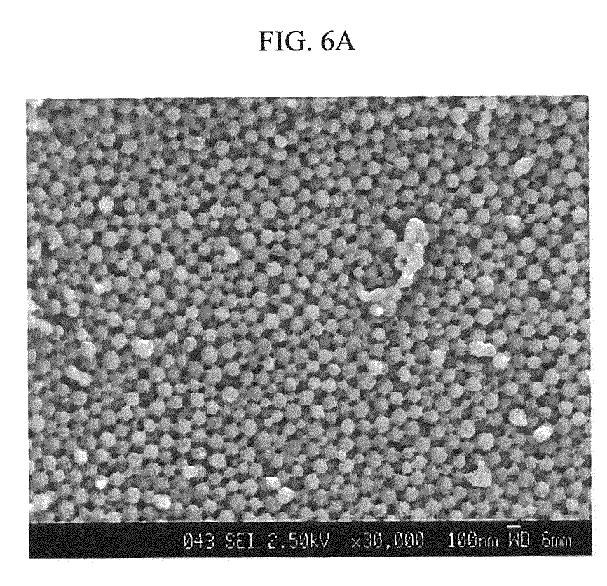

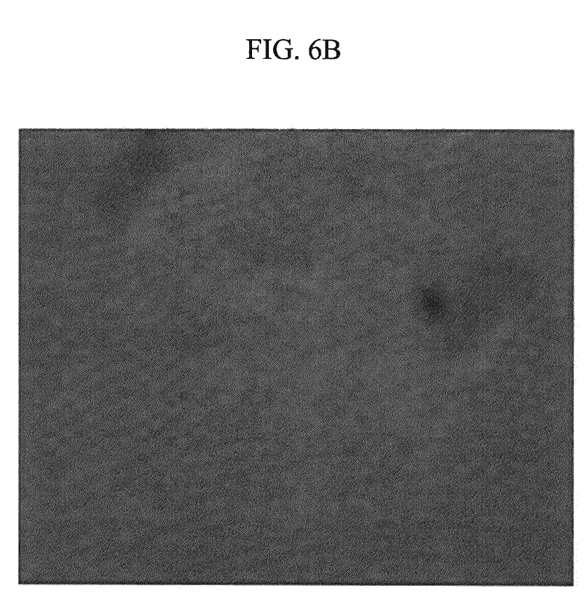

FIGS. 6A and 6B show the state in which the acryl-based resin particles are swelled. FIGS. 6A and 6B are microscope photographs of an acryl-based resin obtained from emulsion polymerization. FIG. 6A shows an example of the state before being dispersed in an organic solvent, and FIG. 6B shows an example of the state after being dispersed in an organic solvent.

As shown in FIG. 6A and FIG. 6B, the acryl-based resin particles obtained by emulsion polymerization according to embodiments of the present invention maintain their particle shape when dispersed in an organic solvent.

The particle diameter of the acryl-based resin after swelling may be increased, for example, to about three times the particle diameter before swelling. The swelled particles of the acryl-based resin are shrunk by removing the organic solvent during the drying and baking processes. However, the shrinkage rate is excessively high if the particle diameter of the acryl-based resin particles after swelling is increased to more than about three times the particle diameter before swelling, resulting in a weakening of the mechanical strength of the obtained coating film 130.

In addition, the acryl-based resin is prepared by emulsion polymerization in order to swell the acryl-based resin particles in the organic solvent. If the acryl-based resin is prepared by another polymerization method (such as, e.g., solution polymerization or suspension polymerization), the particles may not maintain their particle shape during dispersion in an organic solvent, and may increase the sticking property of the glass paste composition, thereby making it difficult to handle the paste and to perform the patterning process.

In other words, according to embodiments of the present invention, the acryl-based resin is not completely dissolved in the organic solvent and the particles maintain their shape, thereby improving the workability of the glass paste composition for patterning processes such as screen printing, dispensing, and the like, as compared to using the other acryl-based binders.

### Organic Solvent

The organic solvent for the glass paste composition according to embodiments of the present invention is not particularly limited. However, considering the process of manufacturing the dye sensitized solar cell 1, it is not desirable for the solvent to be dried during extraction of the solid, which may occur if the organic solvent is dried too rapidly at an excessively high temperature. In this regard, the organic solvent for the glass paste composition according to embodiments of the present invention may have a boiling point of about 150° C. or higher. In some embodiments, for example, the organic solvent has a boiling point of about 180° C. or higher. Nonlimiting examples of the organic solvent include terpene-based solvents (e.g., terpineol and the like) and carbitol-based solvents (e.g., butyl carbitol, butyl carbitol acetate, and the like).

### Other Additives

The glass paste composition according to embodiments of the present invention may further include additives for improving the dispersion of the glass frit or resin, or for adjusting the rheology, if desired. The additive may include, for example: a nonparticulate polymer for adjusting the viscosity for screen printing or the like, or for improving the dispersion of the glass frit; a thickener for adjusting the rheology; a dispersing agent for improving the dispersion of the glass paste composition, and the like.

The nonparticulate polymer may include, for example, an acryl-based polymer obtained by suspension polymerization or solution polymerization. The thickener may include, for example, a cellulose-based resin such as ethyl cellulose and the like, or a polyoxy alkylene resin such as polyethylene glycol and the like. In addition, the dispersing agent may include, for example, an acid such as nitric acid or the like, acetyl acetone, polyethylene glycol, Triton X-100, and the like.

### Viscosity of the Glass Paste Composition

According to embodiments of the present invention, when the glass paste composition has a viscosity within the following range, it facilitates the patterning of the glass paste composition. The patterning may performed by screen printing or a coating method using a dispenser.

First, in screen printing, the glass paste composition may be transcribed to the electrode substrate 10 from a screen mesh using a squeegee at a transcription speed of about 100 sec⁻¹ to several hundred sec⁻¹. When the transcription speed is within this range, the glass paste composition may have a viscosity of about 1 Pa·sec to about 100 Pa·sec. In some embodiments, for example, the glass paste composition has a viscosity of about 1 Pa·sec to about 10 Pa·sec. When the glass paste composition has a viscosity within this range, it facilitates the patterning of the glass paste composition.

In coating using a disperser, the transcription speed of the glass paste composition at the terminal end of a nozzle may range from several thousand sec⁻¹ or several ten thousand sec⁻¹ when the dispenser has a nozzle diameter of more than about 100 μm, and high-speed discharge is used to ensure productivity. When the transcription speed is within this range, the glass paste composition may have a viscosity of about 10 Pa·sec or less. In some embodiments, for example, the glass paste composition has a viscosity of about 3 Pa·sec or less. In other embodiments, the glass paste composition has a viscosity of about 1 Pa·sec or less. When the glass paste composition has a viscosity within these ranges, it facilitates the patterning of the glass paste composition.

According to some embodiments, the glass paste composition may be measured for viscosity using a rheometer (i.e., viscoelasticity measurer) at a temperature of about 23° C.

### Viscoelasticity of Glass Paste Composition

When the glass paste composition has a viscoelasticity within the following ranges, it facilitates the patterning of the glass paste composition.

According to some embodiments, the patterning may be performed by screen printing or coating using a dispenser.

According to some embodiments, the viscoelasticity may be measured using a rheometer (i.e., viscoelasticity measurer).

It is estimated that the viscoelasticity is increased as much as the force (first normal stress (NF)) is increased in the vertical direction to the stressed direction when the material is stressed, but since the NF is increased as much as the viscosity of the paste composition is increased, the value found by dividing the NF by the viscosity measured by a rheometer (measuring temperature: 23° C.) is a reference of assessing viscoelasticity. It is found that, when the coating process is screen printing or coating using a dispenser, viscoelasticity is suitable when the value obtained by dividing the NF by the viscosity is less than a threshold value. For example, in some embodiments, the value found by dividing the NF when the glass paste composition has a shear speed of about 4000 sec⁻¹ by the viscosity at that moment is about 10,000 or less. In some embodiments, for example, the value found by dividing the NF when the glass paste composition has a shear speed of about 4000 sec⁻¹ by the viscosity at that moment is about 4000 or less. When the value found by dividing the NF when the glass paste composition has a shear speed of about 4000 sec⁻¹ by the viscosity at that moment is within these ranges, a desirable pattern may be obtained during screen printing or coating using a dispenser.

### Method of Manufacturing Dye Sensitized Solar Cell

The structure of the dye sensitized solar cell 1 according to embodiments of the present invention has been described above. A method of manufacturing the dye sensitized solar cell 1 according to embodiments of the present invention will now be described.

### Providing a Positive Electrode

First, a transparent conductive oxide (TCO) such as indium tin oxide (ITO), tin oxide (SnO₂), fluorine-doped tin oxide (FTO), antimony-included tin oxide (ITO/ATO), zinc oxide (ZnO₂), or the like is coated on the surface of the substrate 2 by sputtering or the like to provide a transparent electrode 110. Then, a paste composition including a highly conductive metal or alloy (such as Ag, Ag/Pd, Cu, Au, Ni, Ti, Co, Cr, Al, or the like), a resin, a solvent, and the like is coated on the transparent electrode 110 to provide a structure having good photoelectric conversion efficiency (for example, a comb tooth shape).

The metal or alloy may be coated by, for example, screen printing, coating using a dispenser, spin coating, coating using a squeegee, dip coating, spray-coating, coating using a roller, die coating, Inkjet printing, metal masking, or the like, but is not limited thereto. In some embodiments, the metal or alloy is coated by screen printing or coating using a dispenser in order to pattern the current-collecting electrode 120 in a desirable shape.

The coated paste composition is dried at a temperature suitable to remove the solvent (e.g., about 80° C. to about 200° C.) and baked at a temperature suitable to evaporate the resin (e.g., about 400° C. to about 600° C.) and fire the metal oxide particulate 31. This substantially removes the volatilized components from the paste composition to provide a current-collecting electrode 120 on the transparent electrode 110.

A coating film 130 is formed to cover the surface of current-collecting electrode 120. For example, glass frit, an organic binder for binding the same, and additives, if desired, are dispersed in water or an appropriate solvent to provide a glass paste composition. The obtained glass paste composition is coated to cover the entire surface (or at least part of the surface) of the current-collecting electrode 120 (except the part where the lead line 7 is connected).

The glass paste composition may be coated by, for example, screen printing, coating using a dispenser, spin coating, coating using a squeegee, dip coating, spray coating, coating using a roller, die coating, Inkjet printing, or the like.

Since the coating film 130 is formed of a material having low conductivity, the glass paste composition may be coated to sufficiently cover the current electrode 120 with the coating film 130 and to simultaneously decrease the coated area as little as possible in order to improve the photoelectric conversion efficiency.

In order to provide the coating film 130 with a desirable pattern, in some embodiments, the coating may be performed by screen printing or coating using a dispenser.

The glass paste composition is then dried at a temperature suitable to remove the solvent of the coated glass paste composition (e.g., about 80° C. to about 200° C.), and baked at a temperature suitable for evaporating the glass binder and firing the glass frit (e.g., a temperature above the glass transition temperature of the glass frit) so that the volatilized components in the glass paste composition are removed to provide a coating film 130 covering the current-collecting electrode 120.

After providing the coating film 130, the effective surface area of the electrode substrate 10 (i.e., the area capable of photoelectric conversion) is treated with a metal (e.g., platinum, gold, silver, copper, aluminum, rhodium, indium, or the like), a metal oxide (e.g., indium tin oxide (ITO), tin oxide (including F-doped tin oxide), zinc oxide, or the like), a conductive carbon material, a conductive organic material, or the like, by sputtering to provide a counter electrode 4.

Thereby, a positive electrode is provided.

### Providing a Negative Electrode

First, an electrode substrate 10 including a transparent electrode 110, a current-collecting electrode 120, and a coating film 130 is formed on the surface of a substrate 2 in the same manner as described above with respect to the positive electrode.

Then a metal oxide particulate 31 such as TiO₂ (preferably having a particle diameter of a nanometer unit) and an organic binder for binding the same are dispersed in water or an organic solvent to provide a paste composition. The obtained paste composition is coated on the whole effective area (or at least a portion) of the surface of the electrode substrate 10 (i.e., the region capable of photoelectric conversion).

The paste composition may be coated by, for example, spin coating, screen printing, coating using a squeegee, dip coating, spray-coating, coating using a roller, die coating, Inkjet printing, or the like.

The coated paste composition is dried at a temperature suitable to remove the solvent (e.g., about 80° C. to about 200° C.) and baked at a temperature suitable to evaporate the organic binder and fire the metal oxide particulate 31 (e.g., about 400° C. to about 600° C.) so as to remove the volatilized components from the paste composition to provide a metal oxide semiconductor layer.

The substrate 2 and the electrode substrate 10 formed with the metal oxide semiconductor layer are dipped in a sensitizing dye 33 solution (in which the sensitizing dye 33 is dissolved). The substrate 2 and the electrode substrate 10 remain in the sensitizing dye solution for several hours to bind the sensitizing dye 33 with the surface of the metal oxide particulate 31 via the affinity of the surface of the metal oxide particulate 31 with the connecting group 35 of the sensitizing dye 33.

Nonlimiting examples of the solvent in the sensitizing dye solution (hereinafter referred to as “dye solution”) include: alcohol-based solvents such as ethanol, benzyl alcohol, and the like; nitrile-based solvents such as acetonitrile, propionitrile, and the like; halogen-based solvents such as chloroform, dichloromethane, chlorobenzene, and the like; ether-based solvents such as diethylether, tetrahydrofuran, and the like; ester-based solvents such as acetic acid ethyl ester, acetic acid butyl ester, and the like; ketone-based solvents such as acetone, methylethylketone, cyclohexanone, and the like; carbonate ester-based solvents such as diethyl carbonate, propylene carbonate, and the like; hydrocarbon-based solvents such as hexane, octane, benzene, toluene, and the like; dimethyl formamide; dimethyl acetamide; dimethyl sulfoxide; 1,3-dimethyl imidazolinone; N-methylpyrrolidone; water; and the like.

The concentration of the dye solution is not particularly limited, but may range from about 0.01 mmol/L to about 10 mmol/L.

The dipping conditions of the metal oxide semiconductor layer disposed on the electrode substrate 10 into the dye solution is not particularly limited as long as they may provide the desired photoelectric conversion efficiency. In some embodiments, for example, the metal oxide semiconductor layer disposed on the electrode substrate 10 may be dipped at a temperature of about room temperature to about 80° C. for about 1 hour to about 60 hours.

The metal oxide semiconductor layer bound with the sensitizing dye 33 is dried at a temperature suitable for removing the solvent (e.g., about 40° C. to about 100° C.) to provide a photoelectrode 3.

Thereby, a negative electrode is provided.

### Connection of Positive Electrode and Negative Electrode

The obtained positive electrode is placed to face the negative electrode, and spacers (for example, an ionomer resin such as Himilan (trade name) manufactured by Mitsui DuPont Poly Chemical K.K, or the like) are disposed in a connection part around each substrate 2, and the positive electrode and the negative electrode are thermally bound at a temperature of about 120° C.

The electrolyte solution (for example, an acetonitrile electrolyte solution dissolved with LiI and I₂) is injected into an injection hole and spread in the cell to provide a dye sensitized solar cell 1.

A plurality of dye sensitized solar cells 1 may be connected and arranged, if desired. For example, a plurality of dye sensitized solar cells 1 may be arranged in series to increase overall voltage generation.

### EXAMPLES

The following examples are provided for illustrative purposes only, and do not limit the scope of the invention.

In the Examples, the durability (i.e., electrolyte solution resistance) of the coating film to the electrolyte solution are analyzed (see, Examples 1 to 5 and Comparative Examples 1 to 3), and the performance (i.e., photoelectric conversion efficiency) of the dye sensitized solar cells are analyzed (see, Example 6, Example 7, and Comparative Example 4).

### Analyzing Durability (Resistance to Electrolyte Solution)

First, durability of the coating film to an electrolyte solution is analyzed (see, Examples 1 to 5 and Comparative Examples 1 to 3).

### Providing Transparent Electrode

An FTO glass substrate (manufactured by Asahi Glass Co., Ltd., type U-TCO) including a fluorine-doped tin oxide layer (transparent electrode layer) is used as a transparent electrode.

### Providing Counter Electrode

A platinum layer (platinum electrode layer) having a thickness of 150 nm is laminated on an electroconductive layer of an FTO glass substrate (manufactured by Asahi Glass Co., Ltd., type U-TCO) including a fluorine-doped tin oxide layer according to a sputtering method to provide a counter electrode.

### Providing Current-Collecting Electrode

Ag paste (Manufactured by Tanaka Kikinzoku, Type MH1085) is patterned on a glass substrate (Manufactured by Asahi Glass Co., Ltd., Type U-TCO) including a fluorine-doped tin oxide layer (transparent electrode layer) using a screen printing method to provide a stripe having a width of 200 μm, to provide a current-collecting electrode.

### Providing Glass Paste Composition

### Example 1

1.8 g of methacrylic resin having an average particle diameter of 100 nm was obtained by emulsion polymerization and had a de-binding temperature of 390° C. The methacrylic resin, 30 g of B₂O₃—SiO₂—Bi₂O₃-based glass frit having a glass transition temperature (T_{g}) of 405° C., 9.2 g of terpineol (manufactured by Kanto Chemical), and 4.0 g of butylcarbitol acetate (manufactured by Kanto Chemical) were mixed and dispersed in a three roll mixer to provide a glass paste composition.

### Example 2

A glass paste composition was prepared as in Example 1, except that the methacrylic resin had an average particle diameter of 50 nm and a de-binding temperature of 400° C., and the glass frit had a T_{g} of 410° C.

### Example 3

A glass paste composition was prepared as in Example 1, except that the methacrylic resin had an average particle diameter of 500 nm and a de-binding temperature of 390° C., and the glass frit had a T_{g} of 400° C.

### Example 4

A glass paste composition was prepared as in Example 1, except that the methacrylic resin had an average particle diameter of 3000 nm and a de-binding temperature of 410° C., and the glass frit had a T_{g} of 415° C.

### Example 5

A glass paste composition was prepared as in Example 1, except that an acrylic resin prepared by emulsion polymerization was used instead of the methacrylic resin, and the acrylic resin had an average particle diameter of 100 nm and a de-binding temperature of 395° C., and the glass frit had a T_{g} of 405° C.

### Comparative Example 1

A glass paste composition was prepared as in Example 1, except that the methacrylic resin was prepared using suspension polymerization and had de-binding temperature of 390° C., and the glass frit had a T_{g} of 405° C.

### Comparative Example 2

A glass paste composition was prepared as in Example 1, except that the methacrylic resin was prepared using solution polymerization and had a de-binding temperature of 380° C., and the glass frit had a T_{g} of 405° C.

### Comparative Example 3

A glass paste composition was prepared as in Example 1, except that the ethyl cellulose having a de-binding temperature of 455° C. was used instead of the methacrylic resin, and the glass frit had a T_{g} of 405° C.

### Providing a Coating Film

Each of the obtained glass paste compositions were completely coated on a Ag current-collecting electrode and patterned by screen printing to provide a stripe having a width of 300 μm. Then, the glass paste compositions were dried in an oven at 150° C. to remove the solvent and baked at 390° C. for 30 minutes under an air atmosphere to evaporate the organic binder component, thereby providing a coating film.

### Fabricating Test Cells

The glass substrate formed with the obtained current-collector and a FTO glass substrate were hot-pressed using a hot-melt resin of Himilan (thickness 120 μm), and the electrolyte solution was injected into the pre-opened electrolyte solution injection hole, and then the injection hole was sealed with Himilan and a glass cover, thereby providing test cells corresponding to the glass paste compositions of Examples 1 to 5 and Comparative Examples 1 to 3.

### Analyzing Electrolyte Solution Resistance

The test cells obtained from Examples 1 to 5 and Comparative Examples 1 to 3 were allowed to stand at 85° C. for 1000 hours, and the state and shape of the current-collecting electrode and coating film were observed. The results show that no damage is observed by the naked eye in the cells of Examples 1 to 5. In addition, the resistance of the electrode substrate was measured before and after being allowed to stand at 85° C. for 1000 hours. The resistance after being allowed to stand increases only slightly, by at most 1% with respect to the initial value (i.e., resistance before being allowed to stand).

The cells obtained from Comparative Examples 1 and 2 were measured for print patterning of the glass paste composition, but it was impossible to provide a desired pattern due to the high sticking property of the pastes. After the cell obtained from Comparative Example 3 was allowed to stand at 85° C. for 1000 hours, a plurality of corrosion areas were generated in the Ag current-collecting electrode, and the resistance increased by 15% with respect to the initial value.

### Observing Pores

The glass paste compositions obtained from Examples 1 to 5 and Comparative Example 3 were each printed on a glass substrate of a 5 cm×5 cm size and baked according to the same method to observe pores generated in the coating film using a microscope. The coating film was observed for the number and size of pores in a visual field of 96,000 μm², and were counted by a computer.

The results of the pore observation show that Example 1 has a pore number of 1783, an average pore diameter of 1.19 μm, and a maximum pore diameter of 9.5 μm. The results of the pore observation for the remaining Examples and Comparative Examples are shown in the following Table 1.

TABLE 1

| | | | | | | | Current- | |
|---|---|---|---|---|---|---|---|---|
| | | | | | | | collecting | |
| | | | | | | | electrode | |
| | | | | Vanishing | T_{g} of | Maximum | and Coating | Resistance |
| | | | Particle | temperature | glass | pore | film at 85° C., | variation at |
| | | | diameter | of resin | frit | diameter | after 200 | 85° C., after |
| | Resin | Polymerization | (nm) | (° C.) | (° C.) | (μm) | hours | 200 hours |
| Example 1 | methacryl | Emulsion | 100 | 390 | 405 | 9.5 | No change | <1% |
| Example 2 | methacryl | Emulsion | 50 | 400 | 410 | 8.9 | No change | <1% |
| Example 3 | methacryl | Emulsion | 500 | 390 | 400 | 8.8 | No change | <1% |
| Example 4 | methacryl | Emulsion | 3000 | 410 | 415 | 9.1 | No change | <1% |
| Example 5 | acryl | Emulsion | 100 | 395 | 405 | 9.2 | No change | <1% |
| Comparative | methacryl | Suspension | — | 390 | 405 | — | — | — |
| Example 1 | | | | | | | | |
| Comparative | methacryl | Solution | — | 380 | 405 | — | — | — |
| Example 2 | | | | | | | | |
| Comparative | ethyl | — | — | 455 | 405 | 13.1 | Severely | 15% |
| Example 3 | cellulose | | | | | | corrosion of | |
| | | | | | | | Ag electrode | |

From the results, it is understood that the maximum pore diameter is remarkably decreased when the organic binder of the glass paste composition includes the acrylic resin or methacrylic resin obtained by emulsion polymerization and having a de-binding temperature that is lower than the glass transition temperature (T_{g}) of the glass frit, showing substantial prevention of crack generation in the coating film.

### Analyzing Performance of the Dye Sensitized Solar Cell

Dye sensitized solar cells using the glass paste compositions of the above Examples were measured for performance (see, Example 6, Example 7, and Comparative Example 4).

### Transparent Electrode

The transparent electrode includes an FTO glass substrate (manufactured by Asahi Glass Co., Ltd., Type U-TCO) having a fluorine-doped tin oxide layer (transparent electrode layer).

### Providing a Current-Collecting Electrode

Ag paste (manufactured by Tanaka Kikinzoku, MH1085) is patterned on the glass substrate by screen printing to provide a stripe having a width of 200 μm and to provide a current-collecting electrode. The pitch between current-collecting electrodes is 3000 μm.

### Providing Coating Film

### Example 6

As shown in the following Table 2, an electrode substrate including a coating film fabricated using the glass paste composition obtained from Example 1 was made by screen printing.

### Example 7

As shown in the following Table 2, an electrode substrate including a coating film fabricated using the glass paste composition obtained from Example 1 was made by coating using a dispenser.

### Comparative Example 4

As shown in the following Table 2, an electrode substrate including a coating film fabricated using the glass paste composition obtained from Comparative Example 3 was made by screen printing.

### Counter Electrode

A platinum layer (platinum electrode layer) was laminated on an electric conductive layer of an FTO glass substrate (manufactured by Asahi Glass Co., Ltd., Type U-TCO) to a thickness of 150 nm by sputtering to provide a counter electrode.

### Preparing a Paste Composition for Photoelectrode

A paste composition for a photoelectrode was prepared. In particular, for all examples and comparative examples, 3 g of titanium oxide particulate (manufactured by Japan Aerozyl, P-25), 0.2 g of acetyl acetone, and 0.3 g of a surfactant (manufactured by Wako Pure Chemical, polyoxyethylene octylphenylether) were dispersed in 5.5 g of water and 1.0 g of ethanol for 12 hours by a bead mill treatment. 1.2 g of polyethylene glycol (#20,000) was added to the obtained dispersing solution to provide a paste composition.

### Fabricating a Titanium Oxide Electrode

A titanium oxide electrode including a titanium oxide particulate having an area of 100 cm² was fabricated. In particular, in each example and comparative example, the obtained paste composition was coated on the electrically conductive surface of the electrode substrate with the coating film by screen printing, dried at 150° C. and baked at 500° C. for one hour under an air atmosphere to provide a titanium oxide electrode including a porous titanium oxide layer having a layer thickness of 5 μm.

### Adsorbing Sensitizing Dye

The obtained titanium oxide electrode was adsorbed with a sensitizing dye in accordance with the following method. A sensitizing dye N719 (manufactured by Solaronix) for a photoelectric conversion cell was dissolved in ethanol (concentration: 0.6 mmol/L) to provide a dye solution. Then the titanium oxide electrode was dipped in the dye solution and allowed to stand at room temperature for 24 hours.

The dyed surface of the titanium oxide electrode was washed with ethanol and dipped in a 2 mol % alcohol solution of 4-t-butyl pyridine for 30 minutes and dried at room temperature to provide a photoelectrode including a porous titanium oxide layer adsorbed with a sensitizing dye.

### Preparing an Electrolyte Solution

The electrolyte solution having the following composition was prepared. The solvent for dissolving the electrolyte was methoxy acetonitrile.
LiI: 0.1 M
I₂: 0.05 M
4-t-butyl pyridine: 0.5 M
1-propyl-2,3-dimethylimidazolium iodide: 0.6 M

### Assembling Photoelectric Conversion Cells

Using the obtained photoelectrode and counter electrode, a sample of a photoelectric conversion cell (dye sensitized solar cell) shown in FIG. 1 was assembled. In other words, the obtained photoelectrode and counter electrode were mounted by disposing a resin film spacer (manufactured by Mitsui DuPont Poly Chemical, Himilan film (50 μm thickness)) between the electrodes and sealing the cell by hot-pressing. Then, the electrolyte solution was injected into the pre-opened electrolyte solution injection hole to provide an electrolyte solution layer. The electrolyte solution injection hole was sealed by hot-pressing by the same procedure as above. The glass substrate was connected with each line for measuring conversion efficiency.

### Measuring Conversion Efficiency

Photoelectric conversion cells obtained from the Examples and Comparative Examples were measured for conversion efficiency in accordance with the following method. A Solar Simulator (#8116) manufactured by ORIEL was assembled with an air mass filter, and a light source for the measurement was adjusted to provide a light amount of 100 mW/cm². The sample of the photoelectric cell was irradiated and measured for I-V curve characteristics using a KEITHLEY MODEL 2400 source meter. The conversion efficiency η(%) was calculated according to the following Equation 1 using an open voltage (Voc), a short circuit current (Isc), and a filling factor (ff) from the I-V curve characteristics. The conversion efficiencies for each of the Examples and Comparative Example is shown in Table 2.

$$η ( \% ) = \frac{Voc ( V ) \times Isc ( mA ) \times ff}{100 ( mW \text{/} {cm}^{2} ) \times 100 {cm}^{2}} \times 100 \qquad Equation 1$$

TABLE 2

| | | | Initial | Conversion | |
|---|---|---|---|---|---|
| | | | conversion | efficiency | Appearance of |
| | Paste | Patterning | efficiency | at 85° C., 200 | cell at 85° C., after |
| | composition | method | (%) | hours (%) | 200 hours |
| Example 6 | As in Example 1 | Screen printing | 6.3 | 5.9 | No change |
| Example 7 | As in Example 1 | Coating by a | 6.5 | 6.2 | No change |
| | | dispenser | | | |
| Comparative | As in Comparative | Screen | 6.1 | 2.1 | A lot of corrosion |
| Example 4 | Example 3 | printing | | | of Ag electrode |

As shown in Table 2, the photoelectric conversion cells obtained from Examples 6 and 7, and Comparative Example 4 have good initial conversion efficiency. The photoelectric conversion cells were allowed to stand in a constant temperature and humidity chamber at 85° C. and a humidity of 85% for 200 hours. Then, the current-collecting electrode was measured for corrosion (i.e., the appearance of photoelectric conversion cell was observed) and conversion efficiency.

From the results, it is shown that the photoelectric conversion cells according to Examples 6 and 7 maintained the good conversion efficiency and show no changes in appearance. On the other hand, the photoelectric conversion cell according to Comparative Example 4 has remarkably deteriorated conversion efficiency and a lot of corrosion is generated on the Ag current-collecting electrode.

These results show that the pore size present in the coating film is decreased when the coating film is formed to coat the current-collector electrode under the ranged conditions according to embodiments of the present invention. Thereby, it may substantially prevent cracking of the coating film, thereby also substantially preventing contact between the current-collecting electrode and the electrolyte solution, so that corrosion of the current-collecting electrode is substantially prevented. Accordingly, dye sensitized solar cells obtained using the inventive electrode substrates have high efficiency, long life-spans, and high durability.

On the other hand, when the organic binder is prepared by polymerization other than emulsion polymerization (even if it is the same acryl-based resin), the glass paste composition may not be suitable for coating by screen printing or using a dispenser.

In addition, when the organic binder includes a material other than the acryl-based resin (such as ethyl cellulose or the like), a reliable coating film may not be provided since the binder resin is evaporated at a temperature higher than the glass transition temperature (T_{g}) of the glass frit, thereby generating large pores.

Although certain embodiments of the present invention have been described with reference to the attached drawings, the present invention is not limited thereto. For example, according to some embodiments of the present invention, an inorganic semiconductor particulate 31 has a photoelectric conversion function and is sensitized by connecting it to a sensitizing dye on its surface. However, the inorganic semiconductor particulate is not limited to the metal oxide particulate 31 but may include, for example, an inorganic semiconductor particulate that is not a metal oxide. The inorganic semiconductor particulate may include, for example, silicon, germanium, a Group III-Group V semiconductor, a metal chalcogenide, or the like, which are not metal oxides.

While this invention has been described in connection with certain exemplary embodiments, those of ordinary skill in the art will understand that the present invention is not limited to the disclosed embodiments and that various modifications and changes can be made to the described embodiments without departing from the spirit and scope of the appended claims.

What is claimed is:

1. A glass paste composition for a dye sensitized solar cell, comprising
a glass frit having a glass transition temperature;
an organic binder comprising an emulsion polymerized resin comprising at least one of an acrylic resin or a methacrylic resin, the organic binder having a de-binding temperature that is lower than the glass transition temperature of the glass frit; and
an organic solvent.

2. The glass paste composition of claim 1, wherein the organic binder comprises particles having a number average particle diameter of about 50 nm to about 3000 nm.

3. The glass paste composition of claim 2, wherein the particles of the organic binder swell in the organic solvent.

4. An electrode substrate for a dye sensitized solar cell, comprising:
a current-collecting electrode on a transparent conductive substrate, and
a coating film on a surface of the current-collecting electrode, the coating film comprising a glass paste composition baked on the surface of the current-collecting electrode, the glass past composition comprising:
a glass frit having a glass transition temperature;
an organic binder comprising an emulsion polymerized resin comprising at least one of an acrylic resin or a methacrylic resin, the organic binder having a de-binding temperature that is lower than the glass transition temperature of the glass frit; and
an organic solvent.

5. The electrode substrate of claim 4, wherein the organic binder comprises particles having a number average particle diameter of about 50 nm to about 3000 nm.

6. The electrode substrate of claim 5, wherein the particles of the organic binder swell in the organic solvent.

7. A dye sensitized solar cell comprising the electrode substrate of claim 4.

8. A method of preparing an electrode substrate for a dye sensitized solar cell, comprising:
coating a glass paste composition on a surface of a current-collecting electrode on a transparent conductive substrate, the glass paste composition comprising:
a glass frit having a glass transition temperature;
an organic binder comprising an emulsion polymerized resin comprising at least one of an acrylic resin or a methacrylic resin, the organic binder having a de-binding temperature that is lower than the glass transition temperature of the glass frit; and
an organic solvent; and
baking the glass paste composition to form a coating film on a surface of the current-collecting electrode.

9. The method of claim 8, wherein the organic binder comprises particles having a number average particle diameter of about 50 nm to about 3000 nm.

10. The method of claim 9, wherein the particles of the organic binder swell in the organic solvent.

11. The method of claim 8, wherein the glass paste composition is coated using a screen printing method or a dispenser method.
